(19) United States
(12) Patent Application Publication
(10) Pub. No.: US 2024/0379426 A1
(43) Pub. Date: Nov. 14, 2024

(54) METHOD FOR FABRICATING SEMICONDUCTOR DEVICE

(71) Applicant: Samsung Electronics Co., Ltd., Suwon-si (KR)

(72) Inventor: Il Sup KIM, Suwon-si (KR)

(21) Appl. No.: 18/397,713

(22) Filed: Dec. 27, 2023

(30) Foreign Application Priority Data
May 9, 2023 (KR) 10-2023-0059517

(51) Int. Cl. H01L 21/768; H01L 21/311

(52) U.S. Cl. CPC H01L 21/76877; H01L 21/31111; H01L 21/31144; H01L 21/76831

(57) ABSTRACT

A method of manufacturing a semiconductor device capable of improving element performance and reliability uses an etch stop film formed as a homogenous film. The method for fabricating a semiconductor device comprises sequentially forming an etch stop film, an interlayer insulating film, and a hard mask pattern on a substrate. A trench is formed in the interlayer insulating film using the hard mask pattern that exposes a surface of a portion of the etch stop film at a bottom of the trench. At the bottom of the trench, the hard mask pattern and a first portion of the etch stop film are removed by using a first wet etching process. A remaining portion of the etch stop film at the bottom of the trench is removed to expose the lower wiring pattern by using a second wet etching process.

### CROSS-REFERENCE TO RELATED APPLICATION

This application claims priority from Korean Patent Application No. 10-2023-0059517 filed on May 9, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a method for fabricating a semiconductor device, and more particularly, to a method for fabricating a semiconductor device including wiring lines formed in a back-end-of-line (BEOL) process.

### 2. Description of the Related Art

With the development of electronic technology, as down-scaling of semiconductor elements is rapidly progressing in recent years, high integration and low power consumption of semiconductor chips are required. In order to respond to demands for high integration and low power consumption of the semiconductor chips, feature sizes of semiconductor devices are continuously decreasing.

As the feature sizes of the semiconductor devices decrease, a pitch of wirings also decreases. Accordingly, various studies on methods of depositing a conductive material forming wirings are being conducted.

### SUMMARY

Aspects of the present disclosure provide a method of manufacturing a semiconductor device capable of improving element performance and reliability by using an etch stop film formed as a single film.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to some embodiments of the present disclosure, there is provided a method for fabricating a semiconductor device that comprises sequentially forming, on a substrate that includes a lower wiring pattern, an etch stop film, an interlayer insulating film, and a hard mask pattern including an opening above the substrate. The etch stop film may be a continuous homogenous film. A trench is formed in the interlayer insulating film using the hard mask pattern that exposes a surface of a portion of the etch stop film at a bottom of the trench. A first portion of the etch stop film at the bottom of the trench and the hard mask pattern are removed by using a first wet etching process. A second portion of the etch stop film from the bottom of the trench is removed to expose the lower wiring pattern by using a second wet etching process.

According to some embodiments of the present disclosure, there is provided a method for fabricating a semiconductor device that comprises sequentially forming, on a substrate that includes a lower wiring pattern, an etch stop film, an interlayer insulating film, and a hard mask pattern including an opening above the substrate. The etch stop film may be a homogenous aluminum oxide film. A trench is formed in the interlayer insulating film, using the hard mask pattern, that exposes a surface of the etch stop film, the trench having a top portion adjacent the hard mask pattern and a bottom adjacent the etch stop film. A first wet etching process is used to remove the hard mask pattern and a portion of the etch stop film from the trench. A first rounding portion is formed on an upper portion of the interlayer insulating film adjacent the top portion of the trench by using a first dry etching process.

According to some embodiments of the present disclosure, there is provided a method for fabricating a semiconductor device that comprises sequentially forming, on a substrate that includes a wiring pattern, an etch stop film, an interlayer insulating film, and a hard mask pattern. The etch stop film may be a homogenous aluminum oxide film. A trench is formed in the interlayer insulating film using the hard mask pattern to expose the etch stop film at a bottom of the trench, wherein a width of the trench decreases as the trench extends toward the substrate. A portion of the etch stop film from the bottom of the trench and the hard mask pattern are removed by using a first wet etching process. A first rounding portion is formed on the interlayer insulating film using atop corner rounding process. The wiring pattern is exposed by removing a second portion of the etch stop film from the bottom of the trench using a second wet etching process.

### BRIEF DESCRIPTION OF THE DRAWINGS

The above and other aspects and features of the present disclosure will become more apparent by describing in detail exemplary embodiments thereof with reference to the attached drawings, in which:

FIGS. 1 to 9 are intermediate step views for describing a method for fabricating a semiconductor device according to some exemplary embodiments.

FIGS. 10 and 11 are intermediate step views for describing a method for fabricating a semiconductor device according to some exemplary embodiments.

FIGS. 12 to 15 are intermediate step views for describing a method for fabricating a semiconductor device according to some exemplary embodiments.

FIGS. 16 to 18 are cross-sectional views for describing semiconductor devices fabricated by a method for fabricating a semiconductor device according to some exemplary embodiments.

### DETAILED DESCRIPTION OF THE EMBODIMENTS

Terms “first”, “second” and the like may be used as labels to describe various elements, components, and/or sections only in order to distinguish one element, component, or section from another element, component or section, and in such instances, it will be understood that these terms provide no additional limitation to the element, component, section, etc. Accordingly, a first element, a first component, or a first section mentioned below may also be referred to elsewhere as a second element, a second component, or a second section.

In the drawings of a semiconductor device fabricated by a method for fabricating a semiconductor device according to some exemplary embodiments, a fin-type transistor (FinFET) including a channel region having a fin-type pattern shape, a transistor including nanowires or nanosheets, and a multi-bridge channel field effect transistor (MBCFET™) are exemplarily illustrated, but the present invention is not limited thereto. The semiconductor device according to some exemplary embodiments may include a vertical FET, a tunneling FET, or a three-dimensional (3D) transistor, etc. The semiconductor device according to some exemplary embodiments may include a planar transistor. In addition, the technical idea of the present disclosure may be applied to two-dimensional (2D) material based FETs and a heterostructure thereof.

In addition, the semiconductor device fabricated by the method for fabricating the semiconductor device according to some exemplary embodiments may also include a bipolar junction transistor, a lateral double-diffused metal oxide semiconductor (LDMOS) transistor, or the like.

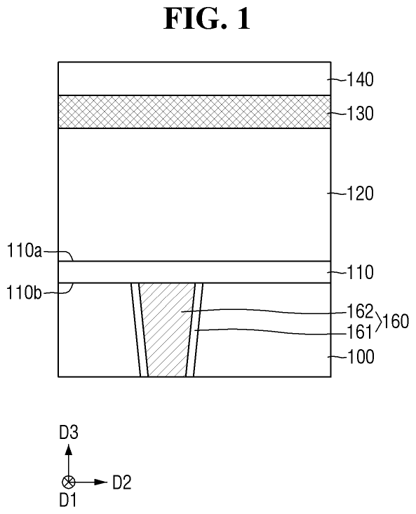

FIGS. 1 to 9 illustrate intermediate step views for describing a method for fabricating a semiconductor device according to some exemplary embodiments.

Referring to FIG. 1, in a method for fabricating a semiconductor device according to some exemplary embodiments, a first etch stop film 110, an interlayer insulating film 120, a lower hard mask pattern 130, and an upper hard mask pattern 140 may be sequentially formed on a substrate 100 including a first lower wiring pattern 160.

Specifically, the first lower wiring pattern 160 is formed in the substrate 100. The substrate 100 may have a structure in which a base substrate and an epitaxial layer are stacked, but is not limited thereto. The substrate 100 may be a silicon substrate or else one of a variety of types of substrates, such as a gallium arsenide substrate, a silicon germanium substrate, a ceramic substrate, a quartz substrate, or a glass substrate for a display, and may also be a semiconductor on insulator (SOI) substrate. In the following, a silicon substrate will be described as an example. In addition, the substrate 100 may have a form in which an insulating film is formed on the silicon substrate.

In the method for fabricating the semiconductor device according to the exemplary embodiments of the present disclosure, the first lower wiring pattern 160 is described as being a metal wiring, but this is only for convenience of explanation, and the first lower wiring pattern 160 is not limited thereto. That is, the first lower wiring pattern 160 may be a different type of device structure such as a transistor, a diode, or the like formed in the substrate 100, and specifically, may be a gate electrode of a transistor or a source/drain of a transistor.

The first lower wiring pattern 160 included in the substrate 100 may include a conductive material. The first lower wiring pattern 160 includes a first conductive barrier film 161 and a first conductive filling film 162.

The first conductive filling film 162 may include, for example, aluminum (Al), copper (Cu), tungsten (W), cobalt (Co), and a combination thereof.

The first conductive barrier film 161 is formed between the first conductive filling film 162 and the substrate 100. For example, the first conductive barrier film 161 may be formed along a recess in the substrate 100. The first conductive barrier film 161 may include a material such as, for example, tantalum, tantalum nitride, titanium, titanium nitride, ruthenium, cobalt, nickel, nickel boron, or tungsten nitride. Although the first conductive barrier film 161 is illustrated as a single homogenous layer, it may also be formed as a plurality of component layers (e.g., of different materials).

The first etch stop film 110 is formed on the substrate 100 including the first lower wiring pattern 160. The first etch stop film 110 may serve as a capping film protecting the first lower wiring pattern 160.

The first etch stop film 110 may be a single homogenous film (e.g., formed of the same material throughout, such as formed during a single continuous deposition process). One surface 110a of the first etch stop film 110 may be in contact with a first interlayer insulating film 120. The term “contact,” “contacting,” “contacts,” or “in contact with,” as used herein, refers to a direct connection (i.e., touching) unless the context clearly indicates otherwise. The other surface 110b of the first etch stop film 110 may be in contact with the substrate 100. The first etch stop film 110 may include or be, for example, aluminum oxide. The first etch stop film 110 may be formed using, for example, chemical vapor deposition or atomic layer deposition.

The first interlayer insulating film 120 is formed on the first etch stop film 110. The first interlayer insulating film 120 may include, for example, at least one of silicon oxide, silicon nitride, silicon oxynitride, and a low-k material.

The first interlayer insulating film 120 may include, for example, a low-k material to reduce a coupling phenomenon between wirings. In addition, the first interlayer insulating film 120 may include material capable of improving adhesion to the hard mask patterns 130 and 140, such chromium or titanium. In other embodiments, film 120 may include tantalum, tungsten, or be a silicon dioxide film formed using silane.

The low-k material may include or be one or more of a variety of materials, for example, fluorinated silicon dioxide, an air gap, a carbon-based material, such as graphene and carbon nanotubes, flowable oxide (FOX), tonen silazene (TOSZ), undoped silica glass (USG), borosilicate glass (BSG), phosphosilicate glass (PSG), borophosphosilicate glass (BPSG), plasma enhanced tetra ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutene (BCB), SiLK™, polyimide, porous polymeric material, and a combination thereof, but is not limited thereto.

The first interlayer insulating film 120 includes a material having an etch selectivity relative to the first etch stop film 110.

The first interlayer insulating film 120 may be formed using, for example, chemical vapor deposition, spin coating, plasma enhanced CVD (PECVD), high density plasma CVD (HDP-CVD), or the like.

The hard mask patterns 130 and 140 are formed on the first interlayer insulating film 120. The lower hard mask pattern 130 may include, for example, at least one of titanium nitride, titanium, titanium oxide, tungsten, tungsten nitride, tungsten oxide, tantalum, tantalum nitride, and tantalum oxide. The upper hard mask pattern 140 may include, for example, at least one of silicon oxide, silicon nitride, and silicon oxynitride.

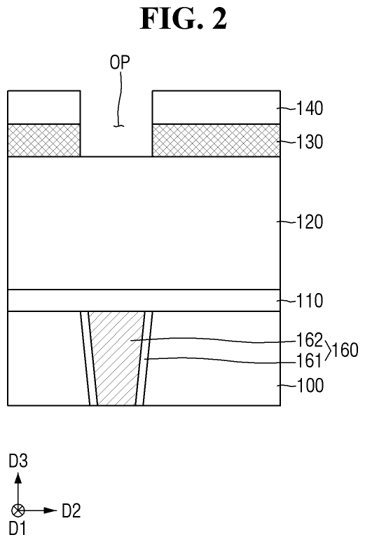

Referring to FIG. 2, an opening OP is formed in the hard mask patterns 130 and 140.

Specifically, in order to pattern the hard mask patterns 130 and 140, a photoresist film pattern may be formed on the upper hard mask pattern 140. The photoresist film pattern is patterned using a photolithographic process. As a result, the photoresist pattern may expose a portion corresponding to the opening OP on the upper hard mask pattern 140.

Subsequently, the opening OP may be formed in the hard mask patterns 130 and 140 by using the photoresist film pattern as an etch mask. After removing the photoresist film pattern, the opening OP may be formed in the lower hard mask pattern 130 by using the upper hard mask pattern 140 as an etch mask. However, the present invention is not limited thereto, and the opening OP may be simultaneously formed in the upper hard mask pattern 140 and the lower hard mask pattern 130 by using the photoresist film pattern formed on the upper hard mask pattern 140 as an etch mask.

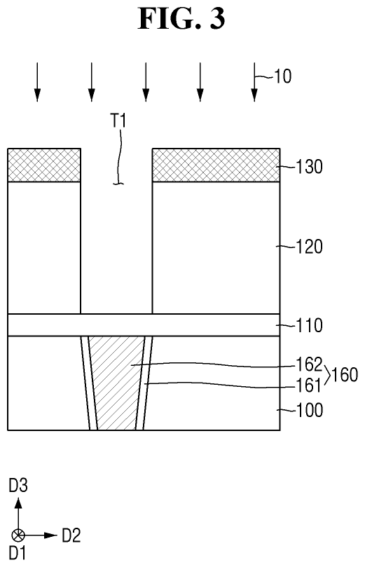

Referring to FIG. 3, a first trench T1 is formed in the first interlayer insulating film 120 by using a first etching process 10. The first trench T1 may expose the first etch stop film 110.

In this example, the first trench T1 extends in a first direction D1. A width of the first trench T1 in a second direction D2 may be constant.

In the method for manufacturing a semiconductor device according to some exemplary embodiments, the first direction D1 and the second direction D2 may be directions in which wirings extend. A third direction D3 perpendicular to the first direction D1 and the second direction D2 may be a thickness direction of the wiring.

In the first etching process 10, the lower hard mask pattern 130 may be used as an etch mask. The first etching process 10 may be, for example, a dry etching process. An etch selectivity exists between the first interlayer insulating film 120 and the first etch stop film 110.

While the first trench T1 is formed in the first interlayer insulating film 120, the upper hard mask pattern 140 disposed on the lower hard mask pattern 130 may be removed. However, the present invention is not limited thereto. For example, after the opening OP is formed in the lower hard mask pattern 130 and the upper hard mask pattern 140 in FIG. 2, the upper hard mask pattern 140 has been removed.

An upper surface of the first etch stop film 110 exposed through the first etching process 10 is illustrated as being flat, but embodiments are not limited thereto. For example, the upper surface of the first etch stop film 110 may not be flat, e.g., curved or irregular. Further, the upper surface of the first etch stop film 110 exposed through the first etching process 10 may be lower than an upper surface of the first etch stop film 110 disposed between the substrate 100 and the first interlayer insulating film 120.

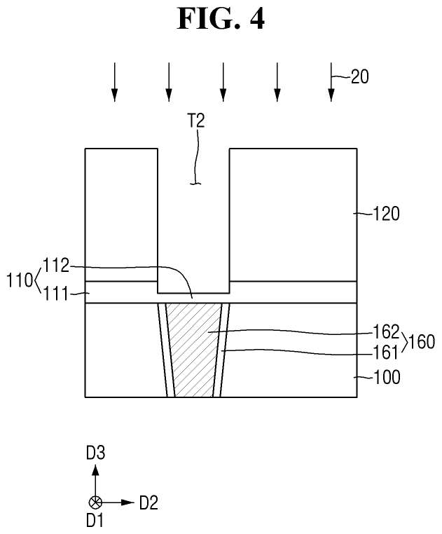

Referring to FIG. 4, a second trench T2 is formed by removing the lower hard mask pattern 130 on the first interlayer insulating film 120 by using a second etching process 20. The second trench T2 may expose the first etch stop film 110, having a bottom surface of the etch stop film 110 (the etch stop film 110 at the bottom of the second trench T2 may have a reduced thickness resulting from the second etching process).

Specifically, in the second etching process 20, the lower hard mask pattern 130 may be removed and a portion of the first etch stop film 110 exposed by the first trench T1 may be removed.

The second etching process 20 may be a wet etching process that uses a wet etchant having an etching selectivity with respect to the first interlayer insulating film 120 and the lower hard mask pattern 130.

The first etch stop film 110 includes a first portion 111 and a second portion 112. The first portion 111 is portion disposed between the first interlayer insulating film 120 and the substrate 100. The second portion 112 is the portion exposed by the second trench T2. That is, the second portion 112 overlaps the second trench T2 in the third direction D3.

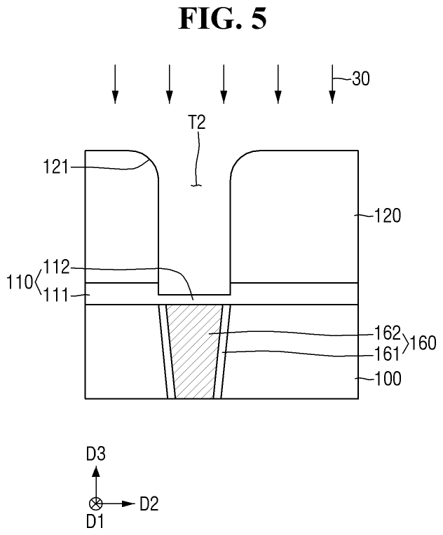

Referring to FIG. 5, a first rounding portion 121 is formed on the first interlayer insulating film 120 by using a third etching process 30.

The third etching process 30 may be a dry etching process. The dry etching process may be, for example, a top corner rounding (TCR) process.

An upper corner of the first interlayer insulating film 120 may, prior to the third etching process 30, have an angular shape. By performing the third etching process 30, the first rounding portion 121 is formed at an upper corner portion of the first interlayer insulating film 120 with a rounded shape.

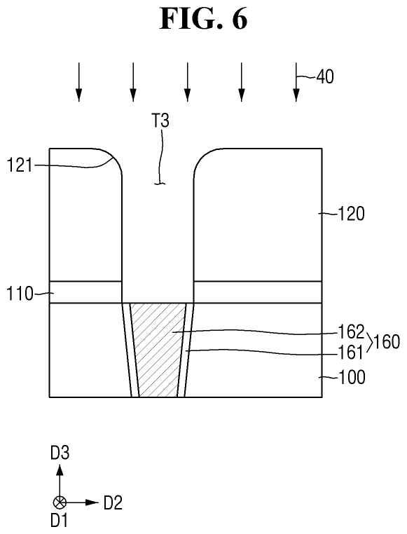

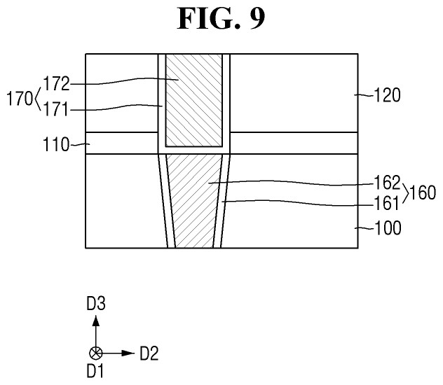

The first rounding portion 121 may help formation of a second lower wiring pattern to be performed later as illustrated in FIG. 9. More specifically, as an upper portion of a second trench T2 is rounded, a second pre-conductive barrier film 171P, as illustrated in FIG. 6, may fill the second trench T2 more easily.

After the third etching process 30 is performed, a height of the second portion 112 of the first etch stop film 110 is illustrated in FIG. 5 as not being changed with respect to the height of the second portion 112 in FIG. 4, but is not limited thereto. In an exemplary embodiment, a thickness of the second portion 112 of the first etch stop film 110 may be reduced after the third etching process 30. As another exemplary embodiment, depending on the thickness of the second portion 112 after the second etching process 20, the second portion 112 may be removed completely by the third etching process 30. In this case, the first lower wiring pattern 160 may be exposed through the third etching process 30.

Referring to FIG. 6, a third trench T3 is formed by removing a portion of the first etch stop film 110 using a fourth etching process 40. The third trench T3 exposes the first lower wiring pattern 160.

The fourth etching process 40 may be a wet etching process. In the fourth etching process 40, a wet etchant having an etching selectivity between the first etch stop film 110 and the first interlayer insulating film 120 is used.

A sidewall of the first etch stop film 110 exposed by the third trench T3 is illustrated as being vertical, but is not limited thereto. For example, the sidewall of the first etch stop film 110 may include a recessed portion and/or be sloped or include a sloped portion.

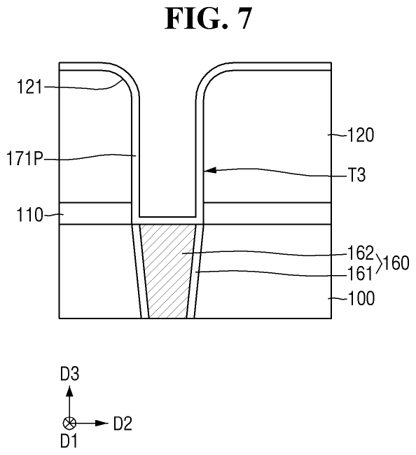

Referring to FIG. 7, a second pre-conductive barrier film 171P is formed along an upper surface of the first interlayer insulating film 120 and the sidewall and bottom surface of the third trench T3, including the first rounding portion 121 of the first interlayer insulating film 120.

Due to the first rounding portion 121 of the first interlayer insulating film 120, the second pre-conductive barrier film 171P may be easily formed in the third trench T3. Specifically, as a size of the semiconductor device decreases, a required feature size of the wiring also decreases. Accordingly, since a conductive material is not uniformly filled in a trench having a narrow width, a reliability of the semiconductor device is reduced. The first rounding portion 121 can ameliorate this negative reliability issue.

By forming the first rounding portion 121 through the TCR process, a barrier film and a conductive material on the barrier film may be easily formed in a trench having a narrow width.

The second pre-conductive barrier film 171P may be formed using, for example, chemical vapor deposition, atomic layer deposition, or physical vapor deposition.

The second pre-conductive barrier film 171P may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material. In the semiconductor device according to some exemplary embodiments, the 2D material may be a metallic material and/or a semiconductor material. The 2D material may include a two-dimensional allotrope or a two-dimensional compound, and may include, for example, at least one of graphene, molybdenum disulfide (MoS₂), molybdenum diselenide (MoSe₂), tungsten diselenide (WSe₂), and tungsten disulfide (WS₂), but is not limited thereto.

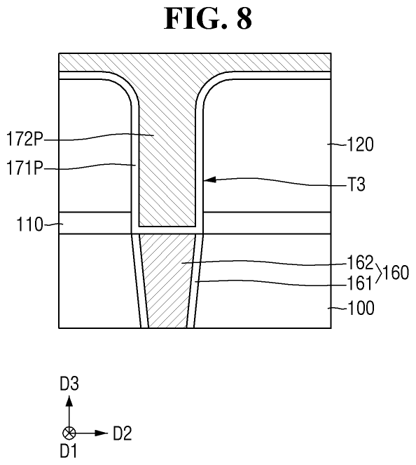

Referring to FIG. 8, a second pre-conductive filling film 172P is formed on the second pre-conductive barrier film 171P.

The second pre-conductive filling film 172P fills a space remaining after the second pre-conductive barrier film 171P is formed in the third trench T3. The second pre-conductive filling film 172P covers the first interlayer insulating film 120.

The second pre-conductive filling film 172P may be formed using, for example, a chemical vapor deposition method or an electroplating method. However, the present invention is not limited thereto.

The second pre-conductive filling film 172P may include, for example, at least one of aluminum (Al), copper (Cu), tungsten (W), cobalt (Co), ruthenium (Ru), silver (Ag), gold (Au), manganese (Mn), molybdenum (Mo), rhodium (Rh), iridium (Ir), RuAl, NiAl, NbB₂, MoB₂, TaB₂, V₂AlC, and CrAlC. When second pre-conductive filling film 172P includes copper (Cu), it may also include, for example, carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), magnesium (Mg), aluminum (Al), or zirconium (Zr).

Referring to FIG. 9, a second lower wiring pattern 170 is formed from films 171P and 172P using a planarization process.

The second lower wiring pattern 170 is formed by removing an upper portion of the second pre-conductive barrier film 171P and an upper portion of the second pre-conductive filling film 172P of FIG. 8 using the planarization process. The second lower wiring pattern 170 extends in the first direction D1.

The second lower wiring pattern 170 includes a second conductive barrier film 171 and a second conductive filling film 172 on the second conductive barrier film 171. The second lower wiring pattern 170 is electrically connected to the first lower wiring pattern 160. The second conductive barrier film 171 may be in contact with the first lower wiring pattern 160.

As the feature size of the semiconductor device decreases, the reliability of the semiconductor device may become a problem due to RC delay of the wiring layer. To address this, in a semiconductor device fabricated according to some exemplary embodiments, a thickness of the first etch stop film 110 may be 30 to 50 Å (angstrom). As the thickness of the first etch stop film 110 decreases, the thickness of the first interlayer insulating film 120 may increase compared to the same size. As a result, as the RC delay of the semiconductor device is reduced, the reliability of the semiconductor device may be improved.

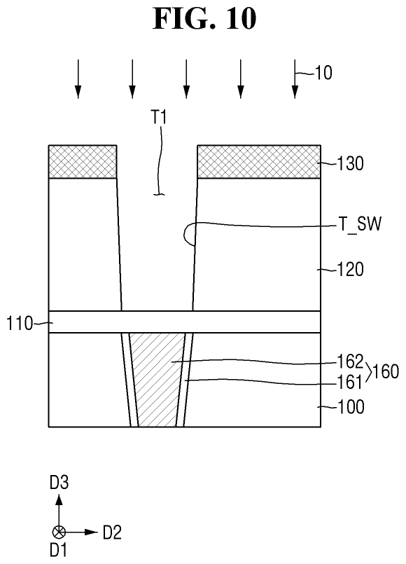

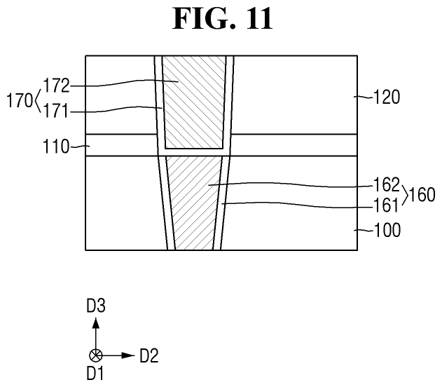

FIGS. 10 and 11 are intermediate step views for describing a method for fabricating a semiconductor device according to some exemplary embodiments. For convenience of explanation, points different from those described with reference to FIGS. 1 to 9 will be mainly described. FIG. 10 is a view for describing a fabricating method step starting after completion of a step as described above for FIG. 2.

Referring to FIG. 10, a first trench T1 is formed in the first interlayer insulating film 120 by using a first etching process 10. The first trench T1 exposes the first etch stop film 110.

In the first etching process 10, the lower hard mask pattern 130 may be used as an etch mask. The first etching process 10 may be, for example, a dry etching process similar to that discussed above for FIG. 3. An etch selectivity exists between the first interlayer insulating film 120 and the first etch stop film 110.

In various embodiments, while the first trench T1 is formed in the first interlayer insulating film 120, the upper hard mask pattern 140 disposed on the lower hard mask pattern 130 may be removed.

The first trench T1 may have a tapered shape. A width of the first trench T1 in the second direction D2 may decrease as the first trench T1 approaches the substrate 100. A sidewall T_SW of the first trench T1 may have an inclined shape.

An upper surface of the first etch stop film 110 exposed through the first etching process 10 is illustrated as being flat, but is not limited thereto. For example, the upper surface of the first etch stop film 110 may be non-flat, e.g., the surface may in part be inclined, curved, and/or irregular. Like the embodiment of FIG. 4, the upper surface of the first etch stop film 110 exposed through the first etching process 10 in FIG. 10 may be lower than an upper surface of the first etch stop film 110 disposed between the substrate 100 and the first interlayer insulating film 120.

Subsequently, the fabricating method described in FIGS. 4 to 8 may be performed. The fabricating method described in FIGS. 4 to 8 may be the same except that, in the FIG. 10 embodiments, the width of the first trench T1 in the second direction D2 decreases.

Referring to FIG. 11, a second lower wiring pattern 170 may be formed by removing an upper portion of the second pre-conductive barrier film 171P and an upper portion of the second pre-conductive filling film 172P of FIG. 8 using a planarization process.

The second lower wiring pattern 170 may have a tapered shape. A width of the second lower wiring pattern 170 in the second direction D2 may decrease as the second lower wiring pattern 170 approaches the substrate 100 in direction D3. The second lower wiring pattern 170 extends in the first direction D1.

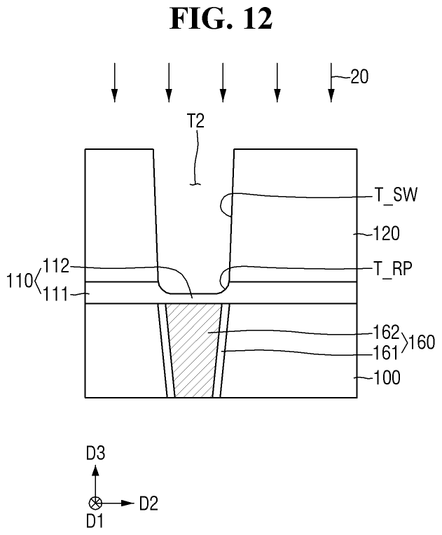

FIGS. 12 to 15 are intermediate step views for describing a method for fabricating a semiconductor device according to some exemplary embodiments. For convenience of explanation, points different from those described with reference to FIGS. 1 to 11 will be mainly described. FIG. 12 is a view for describing a fabricating method step occurring after the method steps of FIG. 10.

Referring to FIG. 12, a second trench T2 is formed by removing the lower hard mask pattern 130 on the first interlayer insulating film 120 by using a second etching process 20. The second trench T2 may etch a portion of the first etch stop film 110.

Specifically, in the second etching process 20, the lower hard mask pattern 130 may be removed. In the second etching process 20, a second trench T2 may be formed by removing a portion of the first etch stop film 110 exposed by the first trench T1.

The second trench T2 may be formed in the first interlayer insulating film 120 and the first etch stop film 110. In other words, the first interlayer insulating film 120 and the first etch stop film 110 include the second trench T2.

The second etching process 20 may be a wet etching process with a wet etchant having an etching selectivity between the first interlayer insulating film 120 and the lower hard mask pattern 130.

A lower portion of the second trench T2 may include a second rounding portion T_RP. The second rounding portion T_RP may be included fully or substantially in the first etch stop film 110. The second rounding portion T_RP may be formed at or near a portion where the sidewall T_SW of the second trench T2 and the bottom surface of the second trench T2 meet. The second rounding portion T_RP may have a round shape. For example, the second rounding portion T_RP may have a shape similar to an arc of a circle, but it is not limited thereto.

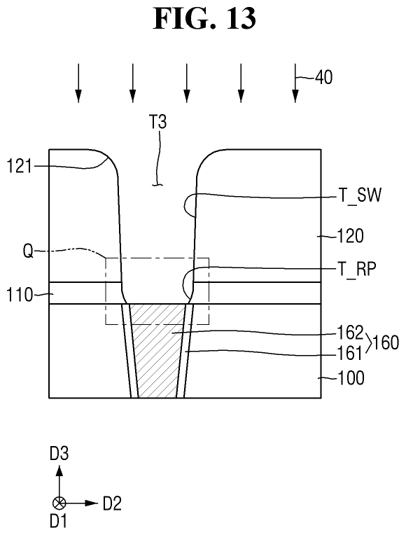

Subsequently, the third etching process 30 of FIG. 5 may be performed. FIG. 13 is a view for describing a fabricating method after the same third etching process 30 of FIG. 5 is performed after the fabricating method in FIG. 12.

Referring to FIG. 13, a third trench T3 is formed by removing a portion of the first etch stop film 110 using a fourth etching process 40. The third trench T3 exposes the first lower wiring pattern 160.

The fourth etching process 40 may be a wet etching process. In the fourth etching process 40, a wet etchant having an etching selectivity between the first etch stop film 110 and the first interlayer insulating film 120 may be used.

A lower portion of the third trench T3 may include a second rounding portion T_RP. The second rounding portion T_RP may be formed completely or substantially on the first etch stop film 110. The second rounding portion T_RP may be formed at or near a portion where the sidewall T_SW of the third trench T3 and the bottom surface of the third trench T3 meet. A shape of the second rounding portion T_RP of the third trench T3 may be similar to the shape of the second rounding portion T_RP of the second trench T2 of FIG. 12, but it is not limited thereto.

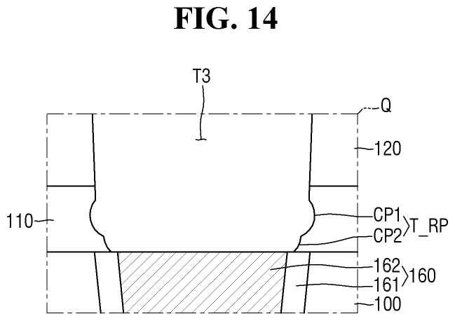

Referring to FIG. 14, in the method for fabricating a semiconductor device according to some exemplary embodiments, the second rounding portion T_RP in first etch stop film 110 may include a first convex portion CP1 and a second convex portion CP2. The first convex portion CP1 and the second convex portion CP2 may have a convex shape toward the first etch stop film 110. The first convex portion CP1 may be connected to the sidewall T_SW of the third trench T3. The second convex portion CP2 may be connected to the bottom surface of the third trench T3.

Unlike the second rounding portion T_RP of FIG. 13, the first convex portion CP1 and the second convex portion CP2 may not be continuously connected. In other words, the second rounding portion T_RP of FIG. 13 may have a shape of a portion of a circle having one center. In FIG. 14, the first convex portion CP1 and the second convex portion CP2 may have a shape of portions of circles having different centers.

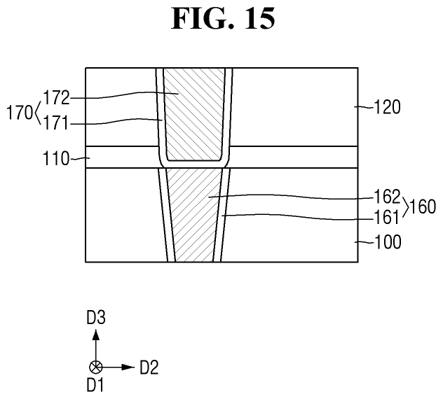

Following FIG. 13 or 14, the fabricating method steps described in FIGS. 7 and 8 may be performed. FIG. 15 is a view for describing a fabricating method step performed after FIG. 8.

Referring to FIG. 15, a second lower wiring pattern 170 may be formed by removing an upper portion of the second pre-conductive barrier film 171P and an upper portion of the second pre-conductive filling film 172P using a planarization process, such as chemical-mechanical polishing. The embodiments are not limited to that example.

The second lower wiring pattern 170 may have a tapered shape. A width of the second lower wiring pattern 170 in the second direction D2 may decrease as the second lower wiring pattern 170 approaches the substrate 100 in direction D3. A lower portion of the second lower wiring pattern 170 may have a rounded shape. The rounded shape may correspond to the second rounding portion T_RP of FIG. 13 or the second rounding portion T_RP of FIG. 14.

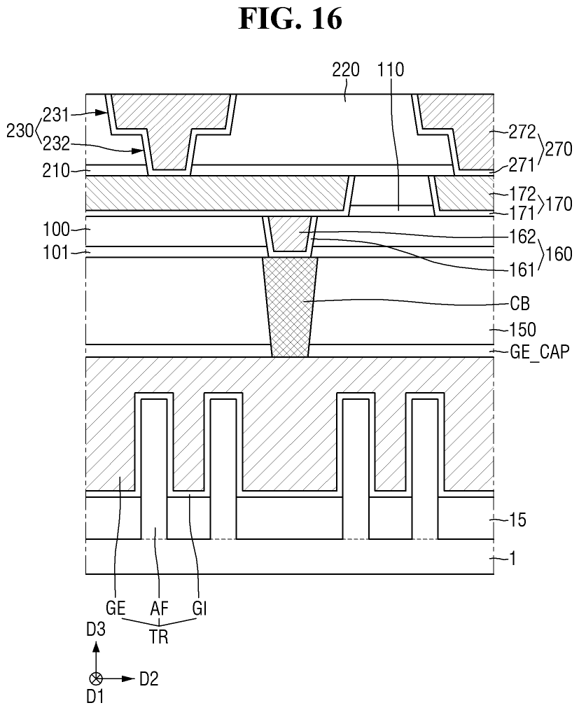

FIG. 16 is a view for describing a semiconductor device fabricated according to some exemplary embodiments.

For reference, FIG. 16 is a cross section of an exemplary semiconductor device taken along a first gate electrode GE.

It is illustrated in FIG. 16 that a fin-type pattern AF extends in the first direction D1 and the first gate electrode GE extends in the second direction D2, but the present invention is not limited thereto.

Referring to FIG. 16, the semiconductor device may include a transistor TR disposed between a substrate 1 and lower wiring patterns 160 and 170. The lower wiring patterns 160 and 170 may be those described elsewhere herein, and formed by any of the methods described herein.

The substrate 1 may be, for example, a silicon substrate or silicon-on-insulator (SOI). Substrate 1 may also include silicon germanium, silicon germanium on insulator (SGOI), indium antimonide, a lead tellurium compound, indium arsenide, indium phosphide, gallium arsenide, or gallium antimonide. Embodiments are not limited thereto.

The transistor TR may include a fin-type pattern AF, a first gate electrode GE on the fin-type pattern AF, and a first gate insulating film GI between the fin-type pattern AF and the first gate electrode GE.

Although not illustrated, the transistor TR may include source/drain patterns disposed on both sides of the first gate electrode GE (e.g., contacting portions of a fin-type pattern AF on opposite sides of the first gate electrode GE (offset from the cross section in the first direction D1)).

The fin-type pattern AF is provided with the substrate 1. The fin-type pattern AF may extend to be elongated in the first direction D1 and protrude in the third direction D3. The fin-type pattern AF may be a portion of the substrate 1, or may include an epitaxial layer grown from the substrate 1 (the description of the fin-type pattern AF being provided with the substrate should be understood to include both of these alternatives). The fin-type pattern AF may be a crystalline semiconductor material, and may be formed of, for example, of an elemental semiconductor material, such as silicon or germanium, or formed of a mixture of silicon and germanium. The fin-type pattern AF may be formed of a compound semiconductor, for example, a group IV-IV, II-VI, or III-V compound semiconductor.

The group IV-IV compound semiconductor may be, for example, a binary compound or a ternary compound including at least two or more of carbon (C), silicon (Si), germanium (Ge), and tin (Sn), or a compound obtained by doping carbon (C), silicon (Si), germanium (Ge), and tin (Sn) with a group IV element. The III-V compound semiconductor may be, for example, one of a binary compound, a ternary compound, or a quaternary compound formed by combining at least one of aluminum (Al), gallium (Ga), and indium (In), which are group III elements, and one of phosphorus (P), arsenic (As), and antimony (Sb), which are group V elements.

A field insulating film 15 may be formed on the substrate 1. The field insulating film 15 may be formed on a portion of a sidewall of the fin-type pattern AF. The fin-type pattern AF may protrude upwardly compared to an upper surface of the field insulating film 15. The field insulating film 15 may include, for example, an oxide film, a nitride film, an oxynitride film, or a combination thereof.

The first gate electrode GE may be disposed on the fin-type pattern AF. The first gate electrode GE may extend in the second direction D2. The first gate electrode GE may intersect the fin-type pattern AF.

The first gate electrode GE may include, for example, at least one of a metal, conductive metal nitride, conductive metal carbonitride, conductive metal carbide, metal silicide, a doped semiconductor material, conductive metal oxynitride, and conductive metal oxide.

The first gate insulating film GI may be disposed between the first gate electrode GE and the fin-type pattern AF and between the first gate electrode GE and the field insulating film 15. The first gate insulating film GI may include, for example, silicon oxide, silicon oxynitride, silicon nitride, or a high-k material having a dielectric constant greater than that of silicon oxide. The high-k material may include, for example, at least one of boron nitride, metal oxide, and metal silicon oxide.

The semiconductor device according to some exemplary embodiments may include a negative capacitance (NC) FET using a negative capacitor. For example, the first gate insulating film GI may include a ferroelectric material film having ferroelectric characteristics and a paraelectric material film having paraelectric characteristics.

The ferroelectric material film may have a negative capacitance, and the paraelectric material film may have a positive capacitance. For example, when two or more capacitors are connected in series with each other and the capacitance of each capacitor has a positive value, a total capacitance decreases as compared with a capacitance of each individual capacitor. On the other hand, when at least one of the capacitances of two or more capacitors connected in series with each other has a negative value, the total capacitance may be greater than an absolute value of each individual capacitance while having a positive value.

When the ferroelectric material film having the negative capacitance and the paraelectric material film having the positive capacitance are connected in series with each other, a total capacitance value of the ferroelectric material film and the paraelectric material film connected in series with each other may increase. A transistor including the ferroelectric material film may have a subthreshold swing (SS) less than 60 mV/decade at room temperature by using the increase in the total capacitance value.

The ferroelectric material film may have the ferroelectric characteristics. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may also be obtained via a process such as CVD, ALD, or sol-gel that deposits a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). A type of dopant included in the ferroelectric material film may vary depending on a type of ferroelectric material included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 atomic % (at %) of aluminum. Here, a ratio of the dopant may be a ratio of aluminum to the sum of hafnium and aluminum.

When the dopant is silicon (Si), the ferroelectric material film may include 2 to 10 at % of silicon. When the dopant is yttrium (Y), the ferroelectric material film may include 2 to 10 at % of yttrium. When the dopant is gadolinium (Gd), the ferroelectric material film may contain 1 to 7 at % of gadolinium. When the dopant is zirconium (Zr), the ferroelectric material film may include 50 to 80 at % of zirconium.

The paraelectric material film has paraelectric characteristics and may include, for example, at least one of silicon oxide and metal oxide having a high dielectric constant. The metal oxide included in the paraelectric material film may include, for example, at least one of hafnium oxide, zirconium oxide, and aluminum oxide, but is not limited thereto.

The ferroelectric material film and the paraelectric material film may include the same material. The ferroelectric material film may have the ferroelectric characteristics, but the paraelectric material film may not have the ferroelectric characteristics. For example, when both the ferroelectric material film and the paraelectric material film include hafnium oxide, a crystal structure of the hafnium oxide included in the ferroelectric material film is different from a crystal structure of the hafnium oxide included in the paraelectric material film.

The ferroelectric material film may have a thickness adapted for providing the ferroelectric characteristics. In some embodiments, the thickness of the ferroelectric material film may be, for example, 0.5 to 10 nm, but not all embodiments are limited thereto. Since a critical thickness representing the ferroelectric characteristics may vary for each ferroelectric material, the thickness of the ferroelectric material film may vary depending on the ferroelectric material.

As an example, the first gate insulating film GI may include one ferroelectric material film. As another example, the first gate insulating film GI may include a plurality of ferroelectric material films spaced apart from each other. The first gate insulating film GI may have a stacked film structure in which a plurality of ferroelectric material films and a plurality of paraelectric material films are alternately stacked.

As illustrated in the example of FIG. 16, a gate capping pattern GE_CAP may be disposed on the first gate electrode GE. A first insulating film 150 may be disposed on the gate capping pattern GE_CAP. A gate contact CB may penetrate through the first insulating film 150 and the gate capping pattern GE_CAP and be in contact with the gate electrode GE.

A second etch stop film 101 may be disposed on the first insulating film 150. The second etch stop film 101 is illustrated as a single homogenous film, but is not limited thereto. For example, the second etch stop film 101 may be a multilayer film including component layers of aluminum oxide and silicon oxide (e.g., alternately stacked).

A substrate 100 may be disposed on the second etch stop film 101. The substrate 100 may be, for example, an insulating layer including an insulating material. A first lower wiring pattern 160 may be disposed in the substrate 100. The first lower wiring pattern 160 may penetrate through the substrate 100 and the second etch stop film 101. The first lower wiring pattern 160 may be in contact with the gate contact CB. The first lower wiring pattern 160 may be in contact with the second lower wiring pattern 170. That is, the first lower wiring pattern 160 may electrically connect the gate contact CB and the second lower wiring pattern 170 to each other.

In a semiconductor device according to some exemplary embodiments, the first lower wiring pattern 160 may be omitted. In this case, the gate contact CB may penetrate through the first substrate 100 and be in contact with the second lower wiring pattern 170.

The second lower wiring pattern 170 may be disposed on the substrate 100. A description of the second lower wiring pattern 170 is the same as that described above.

An upper etch stop film 210 may be disposed on the second lower wiring pattern 170. The upper etch stop film 210 is illustrated as being a single film, but is not limited thereto. The upper etch stop film 210 may be, for example, the same as the first etch stop film 110. As another example, the upper etch stop film 210 may be a multilayer film including aluminum oxide and silicon oxide.

An upper wiring pattern trench 230 may be disposed in the upper insulating film. The upper wiring pattern trench 230 may include an upper line trench 231 and an upper via trench 232.

An upper wiring pattern 270 may contact the second lower wiring pattern 170. The upper wiring pattern 270 may include an upper conductive barrier film 271 and an upper conductive filing layer 272. The upper conductive barrier film 271 may be conformally formed along the sidewalls and the bottom surface of the upper line trench 231 and the sidewalls and the bottom surface of the upper via trench 232. The upper conductive filling layer 272 may fill a portion remaining after the upper conductive barrier film 271 is formed in the upper wiring pattern trench 230. Although it is illustrated that the upper conductive barrier film 271 is formed on surfaces of both of the upper line trench 231 and the upper via trench 232, in other embodiments, the upper conductive barrier film 271 may be disposed only along surfaces of the upper via trench 232 and not along surfaces of the upper line trench 231.

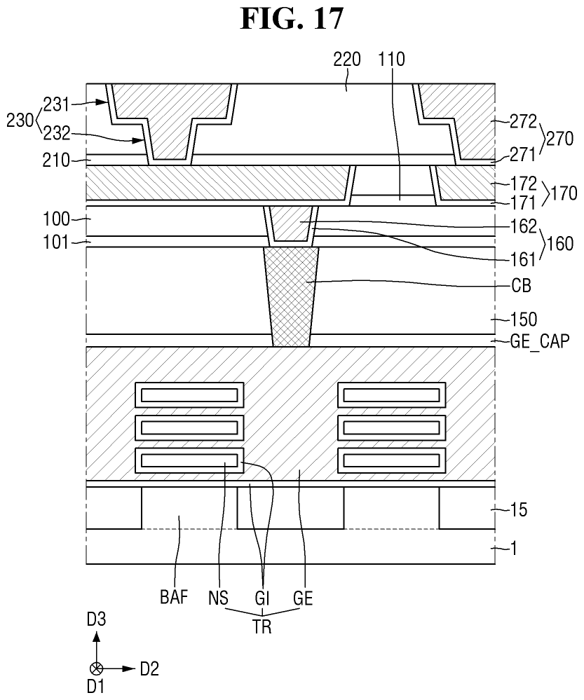

FIG. 17 is a view for describing a semiconductor device fabricated by a method for fabricating a semiconductor device according to some exemplary embodiments. The lower wiring patterns 160 and 170 may be those described elsewhere herein, and formed by any of the methods described herein. For convenience of explanation, points different from those described with reference to FIG. 16 will be mainly described.

Referring to FIG. 17, in the semiconductor device fabricated by the method for fabricating a semiconductor device according to some exemplary embodiments, the transistor TR includes a nanosheet NS, a first gate electrode GE surrounding the nanosheet NS, and a first gate insulating film GI between the nanosheet NS and the first gate electrode GE.

The nanosheet NS may be disposed on a lower fin-type pattern BAF. The nanosheet NS may be spaced apart from the lower fin-type pattern BAF in the third direction D3. The transistor TR is illustrated as including three nanosheets NS spaced apart from each other in the third direction D3, but is not limited thereto. The number of nanosheets NS disposed on the lower fin-type pattern BAF in the third direction D3 may also be greater than three or less than three.

Each of the lower fin-type pattern BAF and the nanosheet NS may include, for example, silicon or germanium, which is an elemental semiconductor material. Each of the lower fin-type pattern BAF and the nanosheet NS may include a compound semiconductor, for example, a group IV-IV, III-V, or other type of compound semiconductor. The lower fin-type pattern BAF and the nanosheet NS may also include the same material or different materials.

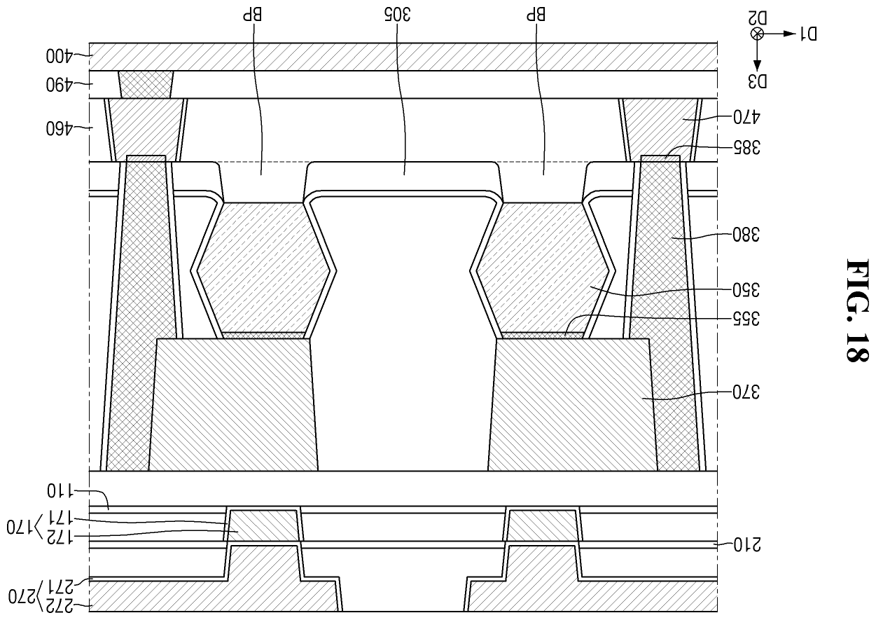

FIG. 18 is a view for describing a semiconductor device fabricated according to some exemplary embodiments. The lower wiring patterns 160 and 170 may be those described elsewhere herein, and formed by any of the methods described herein. For convenience of explanation, points different from those described with reference to FIGS. 16 and 17 will be mainly described.

Referring to FIG. 18, a transistor TR may include a source/drain pattern 350, a source/drain contact 370, and a contact connection via 380. The structure of FIG. 18 may be implemented with and represent each of transistors TR of FIG. 16 or 17 (note the cross sectional view of FIG. 18 taken parallel to D2 and is perpendicular to the cross sections of FIGS. 16 and 17).

The source/drain pattern 350 may be disposed on a lower pattern BP. The source/drain pattern 350 may be disposed on a side surface of the gate electrode GE. The source/drain pattern 350 may be in contact with the fin-type pattern AF of FIG. 16 or the nanosheet NS of FIG. 17.

The source/drain patterns 350 may be spaced apart from each other in the first direction D1. A field insulating film 305 may be disposed between the source/drain patterns 350.

The source/drain contact 370 may be disposed on the source/drain pattern 350.

The source/drain contact 370 is electrically connected to the source/drain pattern 350. The source/drain pattern 350 may include a first silicide film 355. The first silicide film 355 may be in contact with the source/drain contact 370.

The contact connection via 380 may be disposed on one side of the source/drain contact 370. The contact connection via 380 may be in contact with the source/drain contact 370 or otherwise electrically connected to the source/drain contact 370. One end of the contact connection via 380 may be connected to a lower contact 470 to electrically connect the source/drain contact 370 and the lower contact 470 to each other. The lower contact 470 may include a second silicide film 385. The second silicide film 385 may be in contact with the contact connection via 380.

The lower contact 470 may be disposed in a lower insulating film 460. The lower contact 470 may be connected to a rear wiring line 400 as illustrated in the bottom right of FIG. 18. That is, the source/drain pattern 350 may be connected to the rear wiring line 400 through the source/drain contact 370, the contact connection via 380, and the lower contact 470.

Unlike as illustrated, in semiconductor devices according to some exemplary embodiments, the contact connection via 380 may not contact the source/drain contact 370. For example, the contact connection via 380 and the source/drain contact 370 may be spaced apart from each other. In this case, the contact connection via 380 and the source/drain contact 370 may be electrically connected to each other through the first lower wiring pattern 160 and the second lower wiring pattern 170.

Although embodiments of the present disclosure have been described with reference to the accompanying drawings, the present invention is not limited to the above embodiments, but may be implemented in various different forms. A person skilled in the art will appreciate that the present invention may be practiced in other concrete forms without changing the technical spirit or essential characteristics of the inventive aspects of the embodiments of the present disclosure. Therefore, it should be appreciated that the embodiments as described above are not restrictive but illustrative in all respects.

What is claimed is:

1. A method for fabricating a semiconductor device, the method comprising:
sequentially forming, on a substrate that includes a lower wiring pattern, an etch stop film, an interlayer insulating film, and a hard mask pattern including an opening on the substrate, the etch stop film being a homogenous film;
forming a trench in the interlayer insulating film, using the hard mask pattern, that exposes a surface of the etch stop film at a bottom of the trench, the etch stop film including a first portion exposed by the trench;
at the bottom of the trench, removing a portion of the first portion of the etch stop film and the hard mask pattern by using a first wet etching process; and
removing a remainder of the first portion of the etch stop film at the bottom of the trench to expose the lower wiring pattern by using a second wet etching process.

2. The method of claim 1, wherein the etch stop film includes aluminum oxide.

3. The method of claim 1, wherein a thickness of the etch stop film is in a range of 30 to 50 Å (Angstroms).

4. The method of claim 1, further comprising, after the first wet etching process and before the second wet etching process, forming a first rounding portion on an upper portion of the interlayer insulating film adjacent a top of the trench using a top corner rounding (TCR) process.

5. The method of claim 1, wherein the trench has a width that decreases as the trench extends toward the substrate.

6. The method of claim 1, wherein
a first surface of the etch stop film is in contact with the interlayer insulating film, and
a second surface of the etch stop film opposite the first surface is in contact with the substrate.

7. The method of claim 1, further comprising, after the second wet etching process, forming a wiring pattern in the trench.

8. The method of claim 7, wherein the forming of the wiring pattern in the trench includes:
forming a conductive barrier film along sidewalls and a bottom surface of the trench; and
forming a conductive filling film on the conductive barrier film.

9. The method of claim 1, wherein the second wet etching process further includes forming a second rounding portion adjacent the bottom of the trench.

10. The method of claim 9, wherein the second rounding portion includes a convex portion.

11. A method for fabricating a semiconductor device, the method comprising:
sequentially forming, on a substrate that includes a lower wiring pattern, an etch stop film, an interlayer insulating film, and a hard mask pattern including an opening on a substrate, the etch stop film being a homogenous film of aluminum oxide;
forming a trench in the interlayer insulating film, using the hard mask pattern, that exposes a surface of the etch stop film, the trench having a top portion adjacent the hard mask pattern and a bottom adjacent the etch stop film;
removing the hard mask pattern and a portion of a first portion of the etch stop film at the bottom of the trench by using a first wet etching process; and
forming a first rounding portion on an upper portion of the interlayer insulating film adjacent the top portion of the trench by using a first dry etching process.

12. The method of claim 11, wherein
the first dry etching process further includes:
removing a remainder of the first portion of the etch stop film at the bottom of the trench, and
exposing the lower wiring pattern in the trench.

13. The method of claim 11, further comprising, after the first dry etching process, using a second wet etching process to remove a second portion of the etch stop film at the bottom of the trench.

14. The method of claim 13, wherein
in the second wet etching process, a second rounding portion is formed on a lower side of the trench, and
the second rounding portion includes a convex portion.

15. The method of claim 13, further comprising, after the second wet etching process, forming a wiring pattern in the trench.

16. The method of claim 11, wherein the interlayer insulating film includes a low-k dielectric material.

17. The method of claim 11, wherein the hard mask pattern includes at least one of titanium, titanium nitride, titanium oxide, tungsten, tungsten nitride, and tungsten oxide.

18. The method of claim 11, wherein a width of the trench decreases as the trench extends toward the substrate.

19. The method of claim 11, wherein a thickness of the etch stop film is in a range of 30 to 50 Å (Angstroms).

20. A method for fabricating a semiconductor device, the method comprising:
sequentially forming, on a substrate that includes a wiring pattern, an etch stop film, an interlayer insulating film, and a hard mask pattern including an opening on a substrate, the etch stop film being a homogenous film of aluminum oxide;
forming a trench in the interlayer insulating film using the hard mask pattern to expose the etch stop film at a bottom of the trench, a width of the trench decreasing as the trench extends toward the substrate;
at the bottom of the trench, removing a portion of a first portion of the etch stop film and the hard mask pattern by using a first wet etching process; and
forming a first rounding portion on the interlayer insulating film using a top corner rounding process; and
exposing the wiring pattern by removing a remainder of the first portion of the etch stop film at the bottom of the trench using a second wet etching process.
